(19) United States
(12) Patent Application Publication
(10) Pub. No.: US 2008/0268634 A1
(43) Pub. Date: Oct. 30, 2008

(54) DOPANT DIFFUSION BARRIER LAYER TO PREVENT OUT DIFFUSION

(76) Inventor: Haining S. Yang, Wappingers Falls, NY (US)

Correspondence Address: HOFFMAN WARNICK LLC, 75 STATE ST, 14TH FL, ALBANY, NY, 12207, US

(21) Appl. No.: 11/739,406

(22) Filed: Apr. 24, 2007

(51) Int. Cl. H01L 21/44; H01L 23/48

(52) U.S. Cl. 438/653; 257/751; 257/E23.01; 257/E21.476

(57) ABSTRACT

A dopant diffusion barrier layer between silicon and buried oxide is disclosed. In one embodiment, the structure comprises a silicon layer and a substrate separated by an oxide layer; and a diffusion barrier layer located between the oxide layer and the silicon layer. The structure may include an oxide liner between the diffusion barrier layer and the silicon layer.

### BACKGROUND

1. Technical Field

The disclosure relates generally to integrated circuit (IC) chip fabrication, and more particularly, to a dopant diffusion barrier layer between a silicon layer and an oxide layer to prevent boron out diffusion.

2. Background Art

Silicon-on-insulator (SOI) wafers have shown improved device/circuit performance due to reduced parasitic capacitance and source drain leakage. As technology scales, the thickness of silicon over a buried oxide layer needs to be scaled accordingly to maintain a parasitic capacitance reduction benefit or to create a fully depleted substrate. Boron out diffusion from doped source/drain regions to the buried oxide layer becomes a critical issue as silicon thickness is reduced, resulting in a higher percentage loss. This results in a significant increase of source/drain sheet resistance, and a higher impact to scaled devices.

### SUMMARY

A dopant diffusion barrier layer between silicon and buried oxide is disclosed. In one embodiment, the structure comprises a silicon layer and a substrate separated by an oxide layer; and a diffusion barrier layer located between the oxide layer and the silicon layer. The structure may include an oxide liner between the diffusion barrier layer and the silicon layer.

A first aspect of the disclosure provides a method of forming a structure, comprising: forming an oxide layer over a substrate; forming a diffusion barrier layer over the oxide layer; and forming a silicon layer over the diffusion barrier layer.

A second aspect of the disclosure provides a method of forming a structure, comprising: forming a silicon layer over a buried oxide layer and a substrate; forming a diffusion barrier layer between the silicon layer and the buried oxide layer, wherein the diffusion barrier layer is formed by implanting nitrogen into an interface region between the silicon layer and the buried oxide layer and annealing the structure to form the diffusion barrier layer between the buried oxide layer and the silicon layer.

A third aspect of the disclosure provides a structure comprising: a silicon layer and a substrate separated by an oxide layer; and a diffusion barrier layer located between the oxide layer and the silicon layer.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIGS. 1-4 show embodiments of a method according to the disclosure.

FIG. 5 shows an embodiment of a semiconductor structure resulting from the method of FIGS. 1-4.

FIGS. 6-7 show embodiments of another method according to the disclosure.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

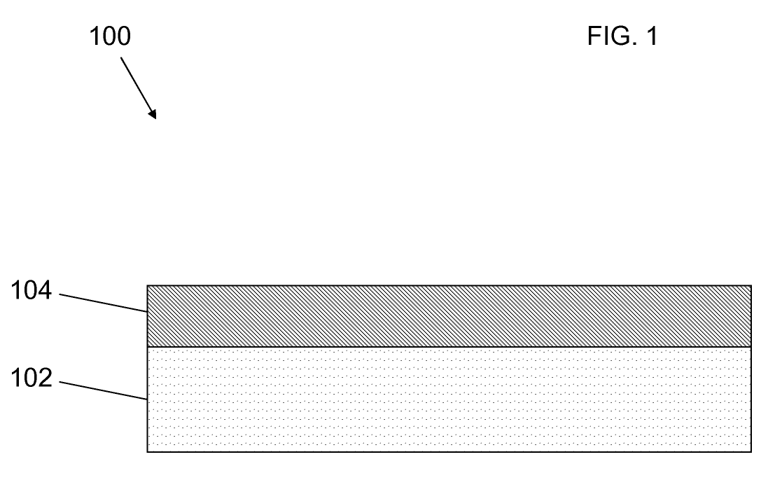

Turning to the drawings, FIG. 1 shows a preliminary structure 100, to which a method according to embodiments of the disclosure will be applied. Although a single structure 100 is shown for the sake of clarity, it should be appreciated that multiple structures are possible. As shown, an oxide layer 104 may be formed over substrate 102, e.g., silicon oxide (SiO₂). Substrate 102 may include a number of materials, including silicon, germanium, silicon germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable materials include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). In addition, substrate 102 may be doped with either an N-type impurity or P-type impurity in a conventional manner. N-type dopants may include but are not limited to: phosphorous (P), arsenic (As), antimony (Sb), while p-type dopants may include but are not limited to: boron (B), indium (In) and gallium (Ga).

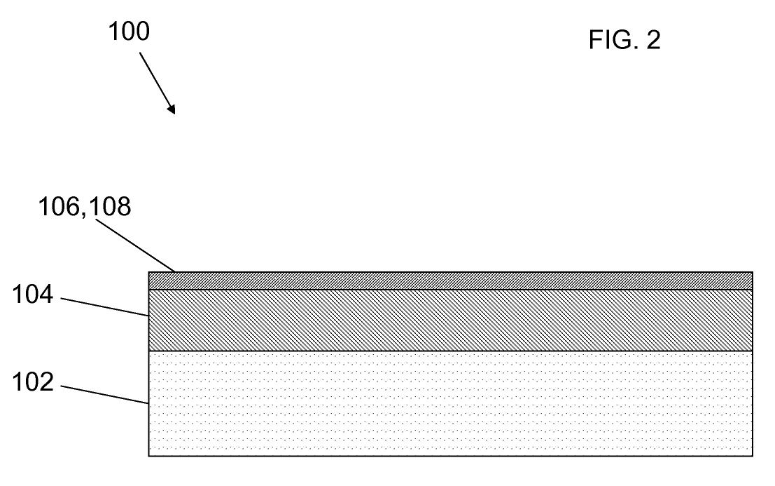

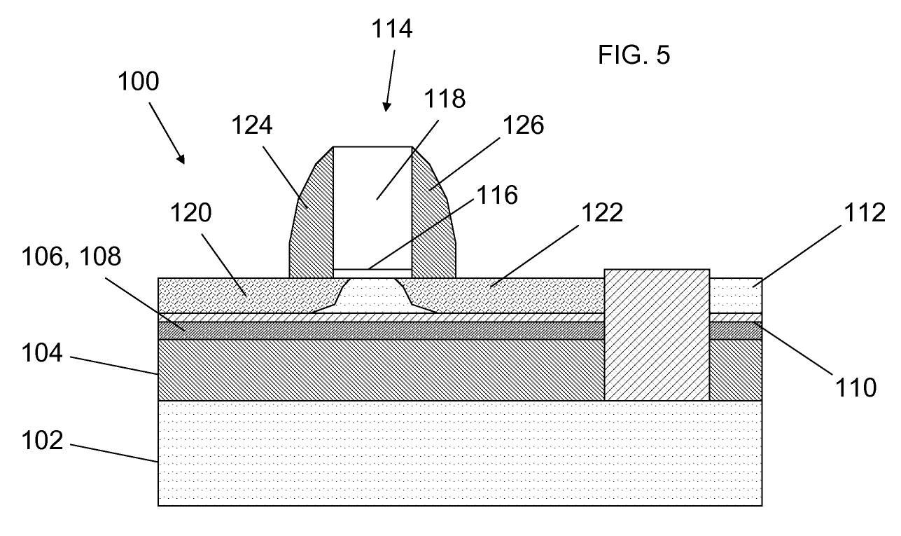

In a next process, as shown in FIG. 2, a nitrogen layer 106 is formed over oxide layer 104 to form diffusion barrier layer 108 over oxide layer 104 to prevent boron diffusion from a source region 120 and a drain region 122 (formed later, as shown in FIG. 5) in the structure. Diffusion barrier layer 108 may include one of: silicon nitride and oxynitride. The formation of diffusion barrier layer 108 between silicon layer 112 and oxide layer 104 prevents boron out diffusion from boron doped source drain regions 120, 122 to oxide layer 104.

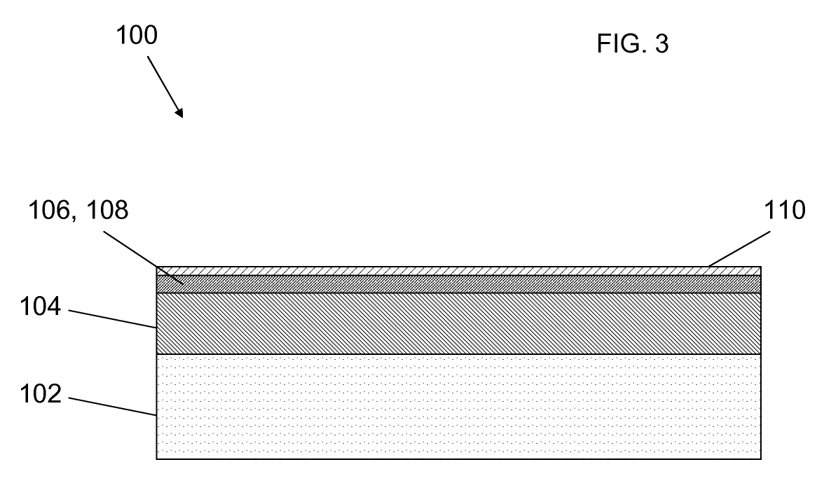

In a next process, as shown in FIG. 3, oxide liner 110 may be formed over diffusion barrier layer 108. Oxide liner 110 has a preferred thickness between approximately 10-100 Å and is formed from an oxidation anneal or oxide deposition. As used herein, deposition may include any now known or later developed techniques appropriate for the material to be deposited including but are not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, and evaporation. Thin (e.g., 10-100 Å) oxide liner 110 is effective to further prevent dopant out diffusion from source/drain 120, 122 (FIG. 5) in a shallow trench isolation (STI) structure.

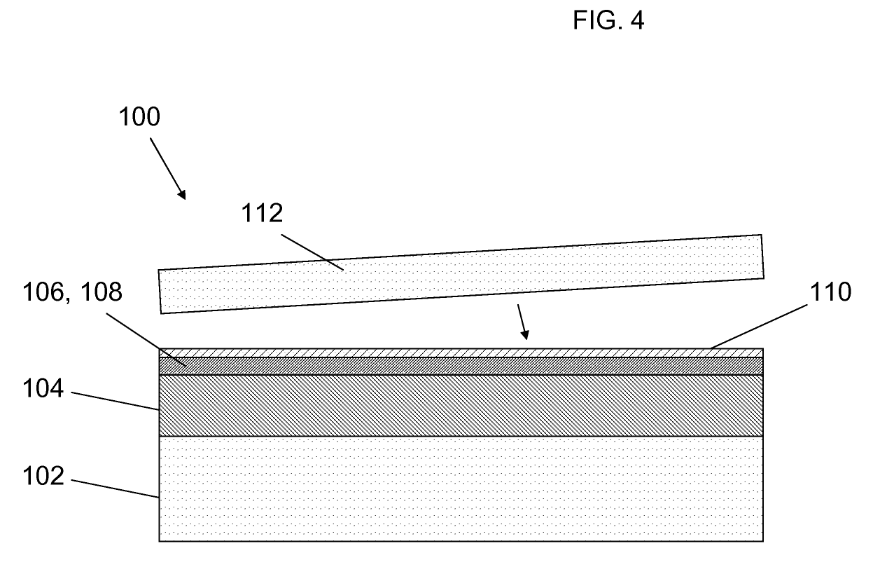

In a next process, as shown in FIG. 4, a silicon layer 112 is formed over diffusion barrier layer 106 and oxide liner 108. Silicon layer 112 may be bonded to oxide liner 108 using any now known or later developed methods to form single structure 100. In addition, silicon layer 112 may be doped with either an N-type impurity or P-type impurity in a conventional manner. N-type dopants may include but are not limited to: phosphorous (P), arsenic (As), antimony (Sb), while p-type dopants may include but are not limited to: boron (B), indium (In) and gallium (Ga).

In a next process, as shown in FIG. 5, a field-effect transistor (FET) 114 may be formed over silicon layer 112. Forming FET 114 includes forming a gate dielectric layer 116 above silicon layer 112 by, for example, growing a (SiO₂) layer by thermal oxidation. Alternatively, gate dielectric layer 116 may include a high-k material with a dielectric constant higher than that of SiO₂, such as hafnium dioxide (HfO₂), hafnium-silicon oxynitride (HfSiON), or hafnium orthosilicate (HfSiO₄). In some embodiments, gate dielectric layer 116 may be a stacked structure, e.g., a thin SiO₂ layer capped with a high-k material. A gate 118 is formed over gate dielectric layer 116. Gate 118 may include a conductive material, such as a doped semiconductor, e.g., polycrystalline Si or polycrystalline SiGe; a metal, e.g., titanium (Ti), tungsten (W), molybdenum (Mo), tantalum (Ta), nickel (Ni), or iridium (Ir); or metal compounds, e.g., titanium nitride (TiN), titanium silicon nitride (TiSiN), tungsten nitride (WN), tantalum nitride (TaN), tantalum silicide (TaSi), nickel silicide (NiSi), or iridium oxide (IrO₂), that provide an appropriate workfunction. A source region 120 and a drain region 122 are formed in silicon layer 112, proximate gate dielectric layer 116. Source and drain regions 120, 122 may be further formed by, e.g., ion implantation of either n-type or p-type dopants. In one embodiment of the disclosure, source/drain regions 120, 122 are doped with boron. FIG. 5 also shows sidewall spacers 124, 126 formed along gate 118. Spacers 124, 126 may include any common spacer material, for example, silicon dioxide (SiO₂), silicon nitride (Si₃N₄), etc.

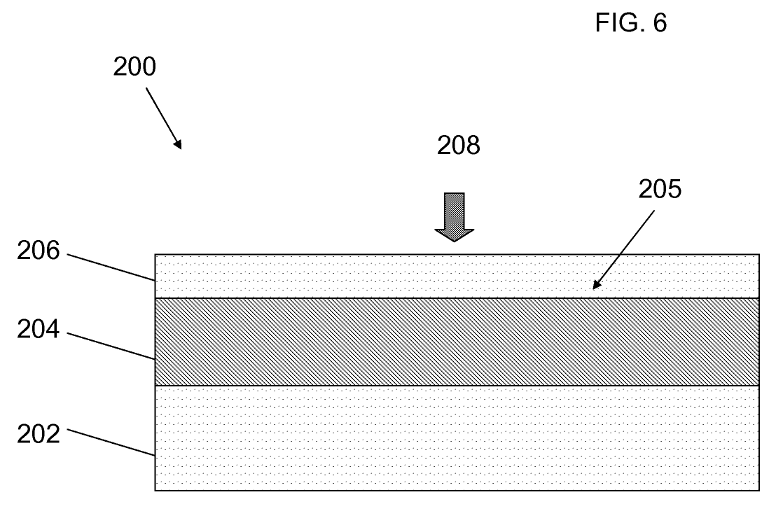

Turning to FIG. 6, another method according to embodiments of the disclosure will be applied. Although a single structure 200 is shown for the sake of clarity, it should be appreciated that multiple structures are possible. As shown, silicon layer 206 may be formed over buried oxide layer 204 and substrate 202. Substrate 202 and silicon layer 206 may include a number of materials, such as those listed above for silicon layer 112 or substrate 102. Silicon layer 206 may be bonded to buried oxide layer 204 using any known method to form single substrate 200.

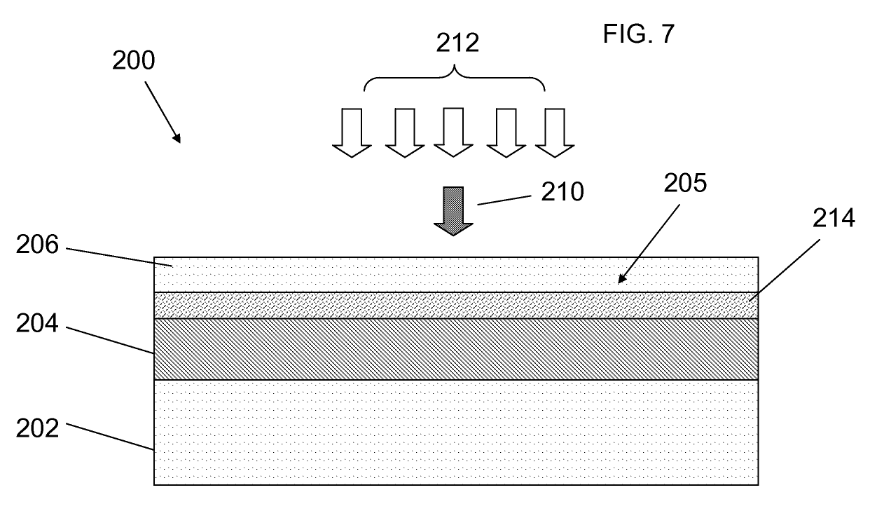

In this embodiment, silicon layer 206 is formed over buried oxide layer 204 prior to the formation of the nitrogen layer (not shown). As shown in FIG. 7, diffusion barrier layer 214 is formed between silicon layer 206 and buried oxide layer 204. Diffusion barrier layer 214 is formed by implanting nitrogen into interface region 205 between silicon layer 206 and buried oxide layer 204 and annealing 212 (FIG. 7) structure 200 to form diffusion barrier layer 214 between buried oxide layer 204 and silicon layer 206. As shown in FIGS. 6-7, oxygen 208 (FIG. 6) and nitrogen 210 (FIG. 7) are implanted into structure 200 following the formation of silicon layer 206. This oxygen/nitrogen ion beam implantation process is followed by a high temperature anneal 212 (FIG. 7) to create buried SiO₂ layer 204 and diffusion barrier layer 214, respectively. Diffusion barrier layer 214 effectively inhibits the diffusion of boron into regions underlying diffusion barrier layer 214.

Although not shown, a FET transistor may be formed over silicon layer 206 by a method similar to that shown in FIG. 5. FET may include forming a gate dielectric layer above silicon layer 206. A gate may be formed over the gate dielectric layer using any now known or later developed methods. Boron-doped source/drain regions may be formed in silicon layer 206, proximate the gate dielectric layer. Sidewall spacers may also be formed along the gate using any now known or later developed methods.

The structures 100, 200 described above are used in the fabrication and/or operation of integrated circuit (IC) chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of various aspects of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of the disclosure as defined by the accompanying claims.

What is claimed is:

1. A method of forming a structure, comprising:
forming an oxide layer over a substrate;
forming a diffusion barrier layer over the oxide layer; and
forming a silicon layer over the diffusion barrier layer.

2. The method of claim 1, further comprising forming an oxide liner over the diffusion barrier layer.

3. The method of claim 1, wherein the diffusion barrier layer includes one of: silicon nitride and oxynitride.

4. The method of claim 1, further comprising forming a field-effect transistor (FET) over the silicon layer.

5. The method of claim 2, wherein the oxide liner is formed by one of: an oxide deposition and an oxidation anneal.

6. A method of forming a structure, comprising:
forming a silicon layer over a buried oxide layer and a substrate; and
forming a diffusion barrier layer between the silicon layer and the buried oxide layer, wherein the diffusion barrier layer is formed by implanting nitrogen into an interface region between the silicon layer and the buried oxide layer and annealing the structure to form the diffusion barrier layer between the buried oxide layer and the silicon layer.

7. The method of claim 6, wherein the diffusion barrier layer includes one of: silicon nitride and oxynitride.

8. The method of claim 6, further comprising forming a field-effect transistor (FET) over the silicon layer.

9. A structure comprising:
a silicon layer and a substrate separated by an oxide layer; and
a diffusion barrier layer located between the oxide layer and the silicon layer.

10. The structure of claim 9 further comprising an oxide liner between the diffusion barrier layer and the silicon layer.

11. The structure of claim 9, wherein the oxide liner has a thickness of approximately 10 A-100 A.

12. The structure of claim 9, wherein the diffusion barrier layer includes one of: silicon nitride and oxynitride.

13. The structure of claim 9 further comprising a field-effect transistor (FET) formed over the silicon layer.
